(19) United States
(12) Patent Application Publication
(10) Pub. No.: US 2025/0334884 A1
(43) Pub. Date: Oct. 30, 2025

(54) WATER-BASED PRETREATMENT FOR PHOTORESIST SCUM REMOVAL

(71) Applicant: Lam Research Corporation, Fremont, CA (US)

(72) Inventors: Kari THORKELSSON, Portland, OR (US); Michael LUKASSER, Ossiach (AT); Patrick Simon DOBROUNIG, Villach (AT); Christian FISCHER, Riegersdorf (AT); Bryan L. BUCKALEW, Tualatin, OR (US)

(21) Appl. No.: 18/860,820

(22) PCT Filed: May 9, 2023
(86) PCT No.: PCT/US2023/021433

§ 371 Date: Oct. 28, 2024

Related U.S. Application Data
(60) Provisional application No. 63/364,510, filed on May 11, 2022.

(51) Int. Cl. G03F 7/32; C25D 5/02; C25D 7/12; C25D 17/00; C25D 17/06

(52) U.S. Cl. CPC G03F 7/322; C25D 5/02; C25D 7/12; C25D 17/001; C25D 17/06

(57) ABSTRACT

Described herein are methods, apparatus, and systems for removing photoresist scum from a substrate. The substrate may be electroplated following photoresist scum removal. In various embodiments, the method involves receiving the substrate in a process chamber, the substrate including a layer of photoresist with features patterned therein, where photoresist scum is present in the features; and exposing the substrate to a solution including water and one or more chemistries capable of removing at least a portion of the photoresist scum from the features.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

As semiconductor device dimensions continue to shrink, such devices become increasingly challenging to fabricate. One area where issues arise is the patterning of features on a semiconductor substrate, and plating within the patterned features.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, and systems for removing photoresist scum on a substrate. The substrate is typically a semiconductor substrate. In many cases, the photoresist scum is removed after the photoresist is developed to form features and before metal is plated into the features.

Various embodiments herein relate to methods, apparatus, and systems for processing a substrate to remove photoresist scum. The photoresist scum is present in recessed features formed in photoresist on the substrate. The photoresist scum is removed without substantially removing the bulk of the photoresist. After removal of the photoresist scum, the features may be filled, for example through electroplating to fill the features with metal. Generally, the photoresist scum is removed by exposing the substrate to a solution having particular chemistry.

In one aspect of the disclosed embodiments, a method of processing a substrate is provided, the method including: receiving the substrate in a process chamber, the substrate including a layer of photoresist with features patterned therein, where photoresist scum is present in the features; and exposing the substrate to a solution including water and one or more chemistries capable of removing at least a portion of the photoresist scum from the features.

In various embodiments, the solution is an ozone solution including water and ozone. In some such embodiments, the ozone solution has an ozone concentration between about 5 ppm and about 500 ppm.

In various embodiments, the solution is a radical initiator solution including water and a free radical initiator. In some such embodiments, the free radical initiator includes one or more chemistry selected from the group consisting of a peroxide, an azo compound, an alkyl halide compound, and combinations thereof. In some embodiments, the free radical initiator includes one or more chemistry selected from the group consisting of hydrogen peroxide, benzoyl peroxide, 2,2′-Azobis(2-methylpropionamidine) dihydrochloride, and combinations thereof. In some embodiments, the free radical initiator solution has a free radical initiator concentration between about 5 ppm and about 1000 ppm. In various embodiments, the free radical initiator decomposes to form radicals that remove at least a portion of the photoresist scum from the features, and the free radical initiator preferentially decomposes near a bottom of the features compared to a top of the features.

In some embodiments, more than one solution may be used. For example, in various embodiments, exposing the substrate to the solution includes exposing the substrate to a first solution followed by exposing the substrate to a second solution, where the first solution is a free radical initiator solution including water and a free radical initiator, and the second solution is an ozone solution including water and ozone. In some embodiments, the free radical initiator decomposes to form radicals, and the radicals formed from the free radical initiator interact with the ozone to form hydroxyl radicals.

In some embodiments, the solution includes both a free radical initiator and ozone such that the substrate is simultaneously exposed to both the free radical initiator and to ozone.

Various techniques may be used for providing the solution to the substrate. For example, in some embodiments exposing the substrate to the solution includes spraying or streaming the solution onto the substrate, or immersing the substrate in the solution. In these or other embodiments, the photoresist may be a negative tone photoresist or a positive tone photoresist. In any of the embodiments herein, the method may further include electroplating metal into the features after exposing the substrate to the solution.

In another aspect of the disclosed embodiments, an apparatus for processing a substrate is provided, the apparatus including a process chamber; an inlet to the process chamber configured to provide a solution to the process chamber; and a controller configured to cause: receiving the substrate in the process chamber, the substrate including a layer of photoresist with features patterned therein, where photoresist scum is present in the features, and providing the solution to the process chamber via the inlet and exposing the substrate to the solution, the solution including water and one or more chemistries capable of removing at least a portion of the photoresist scum from the features.

In various embodiments, the apparatus further includes a nozzle fluidically connected to the inlet, where the nozzle sprays or streams the solution onto the substrate. In some embodiments, a substrate support is configured to immerse the substrate in the solution.

The apparatus may include hardware having particular materials capable of withstanding the chemistry that is used during processing. For example, in various embodiments the inlet includes one or more material selected from the group consisting of polycarbonate, polyether ether ketone (PEEK), polyurethane, polytetrafluoroethylene (PTFE), glass, titanium, stainless steel, and combinations thereof.

In some embodiments, the apparatus further includes a mixing vessel and/or plumbing to prepare the solution by combining (i) the water and (ii) the one or more chemistries capable of removing at least a portion of the photoresist scum. In various embodiments, the controller is further configured to cause preparing the solution by combining (i) the water, and (ii) the one or more chemistries capable of removing at least a portion of the photoresist scum, no more than 10 minutes before the substrate is exposed to the solution.

In various embodiments, the apparatus further includes a second process chamber configured for electroplating, where the process chamber and the second process chamber are provided together such that the substrate can be transferred from the process chamber to the second process chamber under a controlled atmosphere, without removing the substrate from the apparatus.

In another aspect of the disclosed embodiments, a system is provided, the system including: a first process chamber; an inlet to the first process chamber configured to provide a solution to the first process chamber; an outlet to the first process chamber configured to remove solution from the first process chamber; a second process chamber configured for electroplating; and a controller configured to cause: receiving the substrate in the first process chamber, the substrate including a layer of photoresist with features patterned therein, where photoresist scum is present in the features, providing the solution to the first process chamber via the inlet and exposing the substrate to the solution, the solution including water and one or more chemistries capable of removing at least a portion of the photoresist scum from the features, receiving the substrate in the second process chamber, and electroplating metal into the features while the substrate is in the second process chamber.

These and other aspects are described further below with reference to the drawings.

### BRIEF DESCRIPTION OF THE DRAWINGS

FIGS. 1A-1C depict a feature formed in photoresist, illustrating certain issues that can arise when photoresist scum is present in the features.

FIGS. 2 and 3 depict features (e.g. lines) formed in photoresist. FIG. 2 shows the features before any photoresist scum removal, and FIG. 3 shows the features after photoresist scum removal.

FIGS. 4A and 4B illustrate damage and other issues that can occur during a plasma-based photoresist scum removal process.

FIG. 5 shows a flowchart in accordance with various embodiments herein.

FIG. 6 depicts the structure of a particular free radical initiator used in various embodiments herein.

FIG. 7 illustrates a process chamber that may be used to perform liquid-based processing operations described herein, such as exposing a substrate to an ozone solution and/or to a free radical initiator solution.

FIG. 8 illustrates a process chamber that may be used to perform electroplating according to various embodiments herein.

FIG. 9 depicts an apparatus configured to perform liquid-based processing operations described herein, such as exposing the substrate to an ozone solution and/or to a free radical initiator solution, and further configured to perform electroplating, according to various embodiments herein.

FIGS. 10 and 11 present examples illustrating the effectiveness of the photoresist scum removal processes described herein.

FIGS. 12A-12D depict features electroplated at different levels of quality due to the presence of different levels of photoresist scum.

FIG. 13 shows the effectiveness of the photoresist scum removal processes described herein, with reference to the different levels of quality shown in FIGS. 12A-12D.

FIG. 14 illustrates that the disclosed methods can be performed in negative tone photoresist without increasing feature diameter.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Photolithography is commonly used to pattern semiconductor substrates. Such processes typically involve selectively exposing a layer of photoresist on the substrate to radiation, and then developing the photoresist to selectively remove exposed or unexposed portions, thereby forming recessed features in the photoresist. One context in which photolithography is used is through-mask electroplating, where metal is plated into features formed in photoresist. Through-mask electroplating is enabled by a process flow often referred to as the Semi-Additive Process (SAP). Generally, SAP involves (i) deposition of photoresist on a seed layer on a substrate; (ii) selective exposure of the substrate to radiation to define features such as lines, pads, etc. on the photoresist; (iii) selective development of the exposed or unexposed portions of the photoresist to form the features in the photoresist; (iv) electroplating metal into the features in the photoresist; and (v) stripping the remaining photoresist.

When the photoresist is developed, there is typically some amount of photoresist scum that remains at the bottom of the feature, particularly near the sidewalls. This photoresist scum can cause problems in subsequent electroplating processes. For instance, the photoresist scum can prevent deposition on the areas where it is present, leading to formation of defects ranging from feature undercut to failed plating.

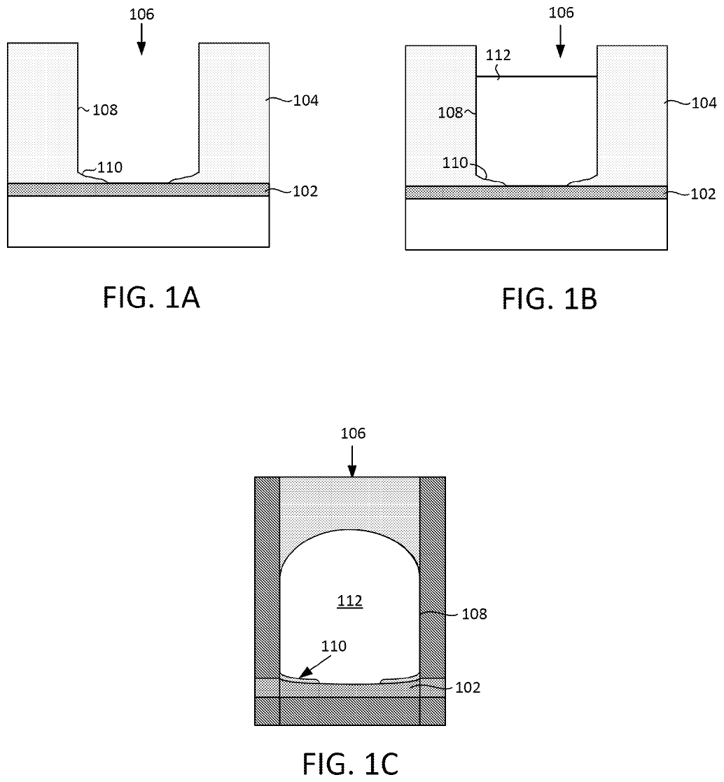

FIGS. 1A-1C illustrate a problem that can occur during electroplating as a result of photoresist scum. In particular, FIG. 1A shows a substrate having a seed layer 102 and photoresist 104 after feature 106 having sidewalls 108 is patterned into the photoresist 104. Photoresist scum 110 is present at the bottom of the feature 106 near the sidewalls 108. FIG. 1B shows the substrate of FIG. 1A after the substrate is subjected to an electroplating process and feature 106 is filled with metal 112. Unfortunately, photoresist scum 110 remains on the substrate. FIG. 1C depicts a substrate analogous to the one shown in FIG. 1B, after removal of photoresist 104. In FIG. 1C, the metal 112 is copper that has been electroplated into the feature 106. Defects caused by photoresist scum 110 are clearly present.

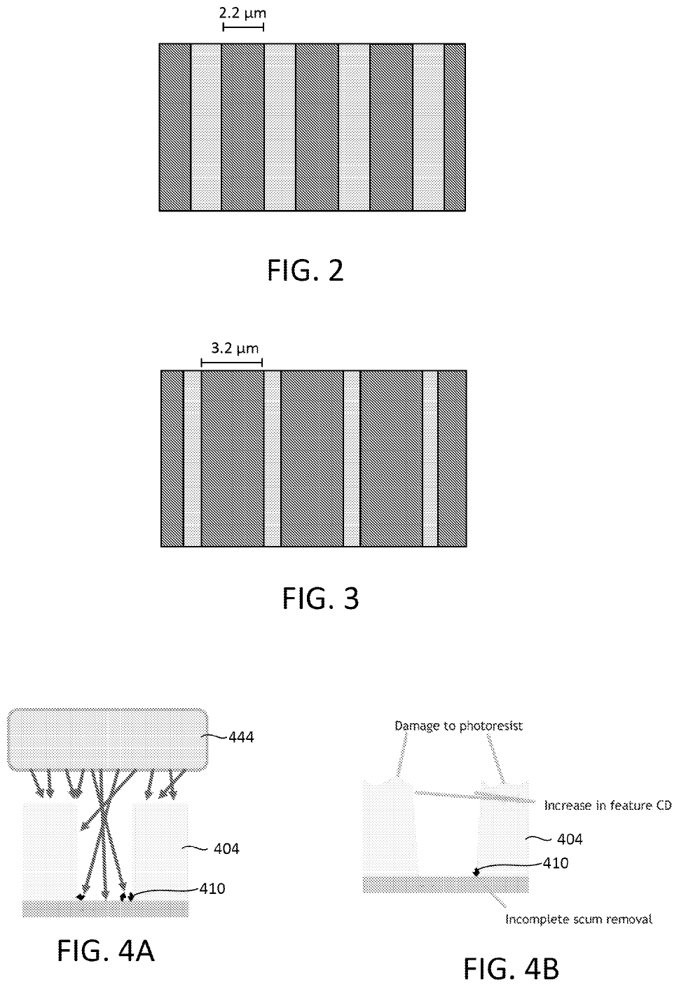

In order to address this issue, a photoresist descum operation is performed. Before the photoresist descum operation, there is a significant amount of photoresist scum at the bottom corners of the feature. After the photoresist descum operation, there is significantly less photoresist scum in this region. It is also common for photoresist descum operations to widen the critical dimensions of features. FIGS. 2 and 3 depict features on a substrate before a photoresist descum operation (FIG. 2) and after a photoresist descum operation (FIG. 3). Prior to descumming, the features in this example have a critical dimension of about 2.2 μm. After descumming, the features have a critical dimension of about 3.2 μm.

In conventional processing, photoresist descumming is typically accomplished by exposing the substrate to plasma. In many cases, an oxygen plasma or oxygen-containing plasma is used. While this strategy is suitable for many applications, it presents certain drawbacks, particularly in the context of developing packaging applications. For instance, plasma-based photoresist descum operations are often ineffective in removing photoresist scum from features that are very small or have large depth:width aspect ratios. The oxygen plasma typically used for photoresist descum operations are very reactive, and tend to react wherever the atoms come into contact with the photoresist. During descumming, the bottom of the feature is more shadowed by the sidewalls and receive substantially less exposure to the plasma compared to the top of the feature. Complete removal of photoresist scum at the bottom of the feature can involve long exposure to plasma, which can lead to an undesirable increase in feature dimensions at the top of the feature.

Another issue with plasma-based photoresist descum operations is that the etching process is isotropic. This means that photoresist is removed both from the bottom of the feature and the sidewalls of the feature. This results in widening the features, as discussed above in relation to FIGS. 2 and 3. When feature sizes are small (e.g., in the context of fine-line redistribution layer (RDL) patterns), this widening can substantially change the feature size. For instance, 1 μm lines separated by 1 μm photoresist can become 1.5 μm or wider lines separated by just 0.5 μm or less photoresist after descumming. These changes in feature geometry can affect electrical properties, and in some cases can even cause electrical shorts in the plated circuit. In addition to changing feature size, a plasma-based descum operation can also result in changing the feature shape. FIGS. 4A and 4B depict a feature in photoresist 404 on a substrate as it undergoes a plasma-based photoresist descum operation. FIG. 4A shows the substrate during the descum operation as it is exposed to oxygen plasma 444, and FIG. 4B shows the substrate after the descum operation. As shown in FIG. 4B, the photoresist descum operation results in damage to the photoresist 404, an increased critical dimension near the top of the feature, and incomplete removal of the photoresist scum 410.

Plasma-based photoresist descum operations are also difficult to control. For example, in many cases short plasma exposure times are desired. However, plasma formation takes a finite amount of time. As a result, there is always some minimum amount of photoresist that a plasma-based descum operation will damage or remove from the substrate. Historically, this was not a big cause for concern. However, as feature sizes continue to shrink, this issue is increasingly problematic.

To overcome these issues, a new photoresist descum operation and apparatus are provided. Instead of a plasma-based process, the new photoresist descum operation is a liquid-based process. The liquid-based process involves exposing the substrate to a solution including chemistry that promotes removal of the photoresist scum. In various embodiments, the photoresist descum operation may be performed in the context of wafer-level packaging applications. In a number of embodiments, the photoresist descum operation may be performed in the context of a Semi-Additive Process as described above. For instance, the photoresist descum operation may be performed after the photoresist is developed and before metal is plated into the features. It has been discovered that the liquid-based photoresist descum operations described herein can be used on both negative photoresist and positive photoresist, as well as ion-implanted photoresist. Generally speaking, any type of photoresist can be used.

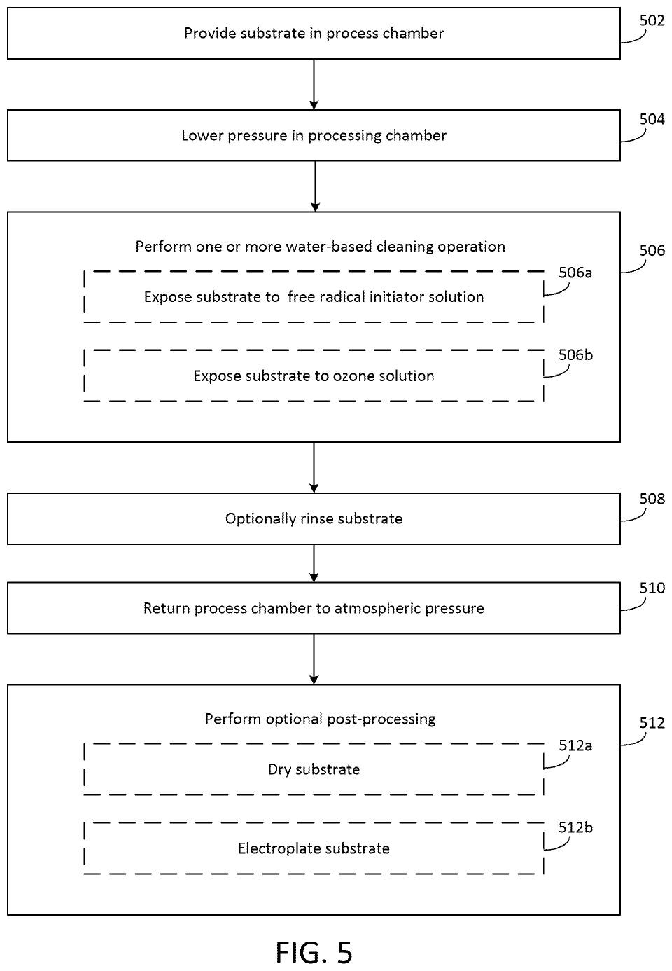

FIG. 5 presents a flowchart describing a photoresist descum and plating process in accordance with various embodiments herein. The method begins with operation 502, where a substrate is provided to a process chamber. The substrate typically includes a conductive seed layer (e.g., a metal seed layer) and a layer of photoresist that has been patterned to include recessed features, for example as shown in FIG. 1A. The seed layer is usually partially exposed and partially covered by photoresist scum. In some embodiments, the features may have a critical dimension (e.g., width) between about 1-500 μm. In some embodiments (e.g., in the context of fine-line RDL), the features may have smaller critical dimensions, e.g., about 1 μm or smaller (in some cases between about 0.5-1 μm). In various embodiments, the features may have a depth:width aspect ratio of about 1:1 or greater, in some cases about 2:1 or greater. The depth of the feature is defined by the thickness of the photoresist. In various embodiments, the photoresist may have a particular thickness. For example, this thickness may have a minimum of about 0.5 μm, or about 10 μm. In these or other embodiments, this thickness may have a maximum of about 5 μm, or about 250 μm. The thickness of the photoresist may depend upon the type of features being patterned into the photoresist. For example, in the context of RDL patterns, the photoresist typically has a thickness of about 5 μm or less, with more advanced patterns at about 0.5 μm to 1 μm thickness. By contrast, in the context of wafer level packaging (WLP) patterning applications, the photoresist typically has a thickness of about 10 μm or greater, up to about 250 μm for very large structures. Generally, the benefits described herein are greatest (as compared to a conventional plasma-based descumming process) when the features have a relatively small critical dimension and/or have a relatively high aspect ratio; however, the processes described herein can be performed on features of any size and shape.

In one example, the process chamber is an electroplating chamber in which a subsequent electroplating process takes place. In another example, the process chamber is a standalone apparatus configured for photoresist descum operations as described herein. In a similar example, such a process chamber could be further configured to perform other limited liquid-based processing operations, including but not limited to pre-wetting or otherwise pre-treating a substrate with liquid. In another example, the process chamber may be incorporated into a larger processing apparatus or system configured for additional purposes. For example, such an apparatus or system may include one or more process chambers configured to perform photoresist descum operations and one or more process chambers configured to perform electroplating and/or related processes. In such embodiments, the process chambers may be implemented as modules that are combined to provide enhanced functionality and a controllable processing and substrate transfer environment. It is understood that the operations described in FIG. 5 may independently occur in any of the types of process chambers, modules, or apparatus described herein, and that such process chambers, modules, or apparatus may be combined as desired, e.g., into an apparatus or system, for a particular application.

At operation 504, the process chamber is sealed and a pressure in the process chamber is reduced by applying vacuum. For instance, in various embodiments the pressure may be reduced to about 100 Torr or less. This reduction in pressure allows for improved penetration of solution into the features in later processing steps and ensures there is no trapped air within the features that would prevent solution from reaching the bottom of the features.

Next, at operation 506 the substrate is subjected to one or more water-based cleaning operations. For example, as described in operation 506a, the substrate may be exposed to a free radical initiator solution. Alternatively or in addition, as described in operation 506b, the substrate may be exposed to an ozone solution. Either of these operations, alone or in combination, may result in removal of photoresist scum from the substrate. In some embodiments, operation 506a is omitted such that operation 506 involves only operation 506b. In other embodiments, operation 506b can be omitted such that operation 506 involves only operation 506a. In other embodiments, operation 506 can involve both of operations 506a and 506b. In some such embodiments, operation 506a is performed before operation 506b. In some embodiments, operation 506a may be performed after operation 506b. In various embodiments, operations 506a and 506b are repeated at least once. In some embodiments, operations 506a and 506b may be performed cyclically. In another embodiment, operations 506a and 506b are performed a single time. In another embodiment, operation 506a is performed twice, separated by operation 506b. Generally speaking, either or both of operations 506a and 506b may be repeated any number of times. Further, operations 506a and 506b may occur sequentially or simultaneously. The substrate may be spun to remove excess solution after either or both of operations 506a and 506b. The process(es) involved in operation 506 may be selected based on a number of factors including, but not limited to: the composition and molecular structure of the photoresist and photoresist scum (e.g., ozone reacts more with C—C bonds, while OH radicals generated by a free radical initiator will react with any C—C bond), the size of the feature, and the depth of the feature. Further, this selection can be affected by a desire for additional radicals, considerations related to whether the substrate will be rinsed with water after operation 506, and any impacts on process time/throughput.

With regard to operation 506a, a number of processing conditions may be controlled. For example, the exposure conditions can be tailored to provide a desired flow rate of free radical initiator solution and a desired exposure duration. In various examples, the free radical initiator solution is sprayed onto the surface of the substrate. In other examples, the substrate may be immersed in the free radical initiator solution. The substrate may be rotated while being exposed to the free radical initiator solution. The reduced pressure achieved in operation 504 allows the free radical initiator solution to penetrate deep into the features. The substrate is exposed to the free radical initiator solution for a desired duration. In various embodiments, this duration may have a minimum of about 5 seconds, or about 30 seconds. In these or other embodiments, this duration may have a maximum of about 60 seconds, or about 10 minutes. This exposure duration ends when the free radical initiator solution is rinsed from the substrate (e.g., when the substrate is exposed to the ozone solution in operation 506b, or when the substrate is exposed to water to rinse the substrate in operation 508 in the absence of operation 506b).

The free radical initiator solution may have a particular concentration in certain embodiments. For example, in some embodiments the free radical initiator may have a minimum concentration of about 5 ppm, about 10 ppm, about 50 ppm, or about 100 ppm, in the free radical initiator solution. In these or other embodiments, the free radical initiator may have a maximum concentration of about 100 ppm, about 200 ppm, about 500 ppm, or about 1000 ppm in the free radical initiator solution. Generally, lower concentration solutions may be used with longer exposure durations, and higher concentration solutions may be used with shorter exposure durations. The concentration should be high enough effectively remove photoresist scum, and low enough to avoid substantial damage to the photoresist. One advantage of relatively higher concentrations is faster processing times. One advantage of relatively lower concentrations is that the photoresist scum removal may be easier to control to provide uniform results across the entire substrate surface.

In some embodiments, a temperature of the substrate, substrate holder, and/or free radical initiator solution may be controlled. For instance, the temperature of one or more of the substrate, substrate holder, and/or free radical initiator solution may have a minimum of about 0° C., or about 10° C. In these or other embodiments, this temperature may have a maximum of about 30° C., or about 50° C. In some cases, no active heating or cooling is used. In some cases, processing occurs at about room temperature. Generally, lower temperatures lead to lower reaction rates, which increases the likelihood that free radical generation will occur at a surface (e.g., the photoresist surface). By contrast, higher temperatures increase free radical generation and speed up processing of the substrate.

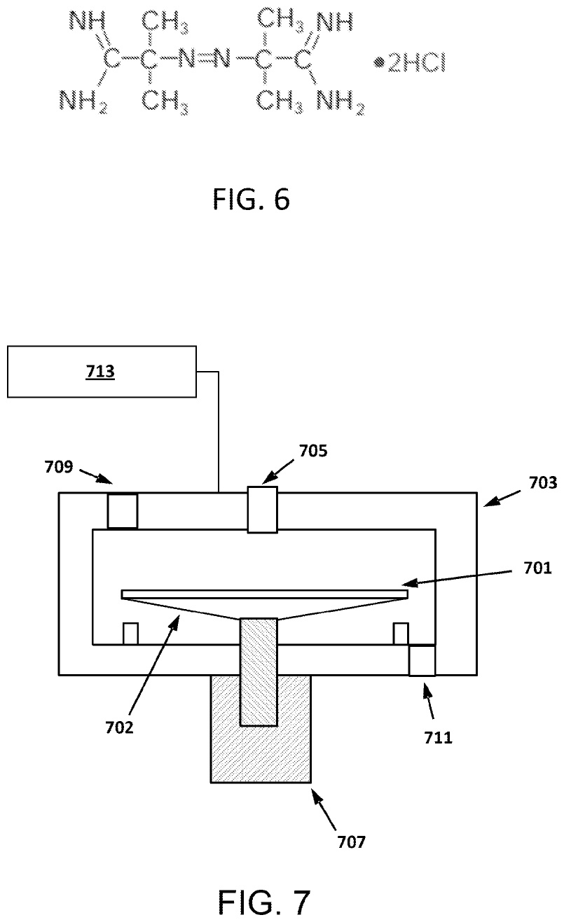

As used herein, a free radical initiator is a chemical species that decomposes to generate radicals upon exposure to UV radiation, heat, or a catalyst. In various embodiments herein, the metal surface of the seed layer acts as a catalyst for an appropriate free radical initiator. Exposure to UV radiation and/or heat could be used alternatively or in addition to the metal seed layer catalyst to drive formation of radicals. Examples of free radical initiators include, but are not limited to, peroxides (e.g., hydrogen peroxide, benzoyl peroxide, etc.), azobisisobutyronitrile (AIBN), 2,2′-Azobis(2-methylpropionamidine) dihydrochloride, and other azo compounds, as well as alkyl halide compounds. AIBN is commonly used as a free radical initiator; however, it is insoluble in water and therefore may not be the best candidate for use in a water-based solution. By contrast, many of the other identified free radical initiators are soluble or miscible in water, and may be more preferred candidates. For reference, the structure of 2,2′-Azobis(2-methylpropionamidine) dihydrochloride is shown in FIG. 6. Upon exposure to appropriate conditions as described above, 2,2′-Azobis(2-methylpropionamidine) dihydrochloride decomposes in water to form nitrogen and two molecules with carbon radicals. Peroxides similarly decompose in water to form hydroxyl radicals. Generally, azo compounds are chemical compounds having the formula R—N═N—R′, where R and R′ can independently be any aryl or alkyl groups. Alkyl halide compounds have the formula R—X, where R is an alkyl group and X is a halogen.

The radicals that are formed from the free radical initiator can react with the photoresist scum to remove it from the substrate surface. In addition, in embodiments where operation 506 involves both exposure to the free radical initiator solution in 506a and exposure to the ozone solution in 506b, the radicals that are formed from the free radical initiator in 506a can react with the ozone in 506b to produce hydroxyl radicals. These hydroxyl radicals can directly react with and remove the photoresist scum, or they can react with the ozone to produce additional hydroxyl radicals.

One advantage of operation 506a is that decomposition of the free radical initiator can be controlled. For example, decomposition can be tuned through application of UV radiation, heat, or exposure to a catalyst to achieve a desired concentration of radicals. The amount of UV radiation, heat, and catalyst provided to the free radical initiator solution can be easily controlled to promote a desired degree of radical formation. Moreover, the use of free radical initiators that decompose upon exposure to a metal catalyst (e.g., the metal of the seed layer) can preferentially promote decomposition at desired locations within the feature. This is a significant advantage over plasma-based photoresist descumming processes. Because the photoresist scum is concentrated at the bottom of the feature, this is where the radicals are most useful. When the radicals are selectively or preferentially generated at the bottom of the feature (compared to the top of the feature or bulk solution), the scum can be effectively removed from the bottom of the feature while minimizing damage to the remaining photoresist. Whereas plasma-based processes often result in greater removal near the top of the features and less removal near the bottom of the features, the liquid-based solutions described herein may have the opposite effect: greater removal at the bottom of the features (where such removal is desired), and less removal near the top of the features (where such removal is not desired). This improvement is significant.

With regard to operation 506b, a number of processing variables may be controlled. For example, the exposure conditions can be tailored to provide a desired flow rate of ozone solution and a desired exposure duration. In various examples, the ozone solution is sprayed onto the surface of the substrate. In other examples, the substrate may be immersed in the ozone solution. The substrate may be rotated while being exposed to the ozone solution. The reduced pressure achieved in operation 504 allows the ozone solution to penetrate deep into the features. The substrate is exposed to the ozone solution for a desired duration. In various embodiments, this duration may have a minimum of about 5 seconds, or about 30 seconds. In these or other embodiments, this duration may have a maximum of about 60 seconds, or about 10 minutes. This exposure duration ends when the ozone solution is rinsed from the substrate (e.g., when the substrate is exposed to water to rinse the substrate in operation 508).

The ozone solution may have a particular concentration in certain embodiments. For example, in some embodiments the ozone may have a minimum concentration of about 5 ppm, about 10 ppm, about 30 ppm, about 50 ppm, or about 100 ppm in the ozone solution. In these or other embodiments, the ozone may have a maximum concentration of about 50 ppm, about 100 ppm, about 200 ppm, about 300 ppm, or about 500 ppm in the ozone solution. In various embodiments, the ozone may be present in the ozone solution at a concentration of about 5 ppm, about 30 ppm, or about 50 ppm. Generally, lower concentration solutions may be used with longer exposure durations, and higher concentration solutions may be used with shorter exposure durations. The concentration should be high enough effectively remove photoresist scum, and low enough to avoid substantial damage to the photoresist. Similar to the free radical initiator solution, one advantage of relatively higher concentrations is faster processing times, and one advantage of relatively lower concentrations is that the photoresist scum removal may be easier to control to provide uniform results across the entire substrate surface.

In some embodiments, a temperature of the substrate, substrate holder, and/or ozone solution may be controlled. For instance, the temperature of one or more of the substrate, substrate holder, and/or ozone solution may have a minimum of about 0° C., or about 10° C. In these or other embodiments, this temperature may have a maximum of about 30° C., or about 50° C. In some cases, no active heating or cooling is used. In some cases, processing occurs at about room temperature.

The ozone in the ozone solution can directly interact with and remove the photoresist scum on the substrate. Ozone is a strong oxidizer and can remove photoresist scum in a similar way that an oxygen plasma does. Further, in embodiments where operation 506 involves exposing the substrate to both the free radical initiator solution in operation 506a and to the ozone solution in operation 506b, the radicals generated from the free radical initiator can interact with the ozone to cause formation of hydroxyl radicals. These hydroxyl radicals can directly interact with and remove the photoresist scum on the substrate. In addition, these hydroxyl radicals can interact with additional ozone molecules to cause formation of additional hydroxyl radicals. Hydroxyl radicals are more reactive than molecular ozone, so the reactivity of the ozone solution can be modulated by promoting or suppressing radical formation. For example, providing a free radical initiator increases the rate at which ozone forms hydroxyl radicals, thereby increasing the reactivity of the solution. As mentioned above, the free radical initiator produces radicals under certain controllable conditions such as exposure to radiation, heat, and/or a catalyst. By selecting a free radical initiator that forms radicals upon exposure to a metal surface (e.g., such as the metal seed layer underlying the patterned photoresist), the radical-generation reaction can occur preferentially or selectively near the bottom of the features, where the photoresist scum is located. The radicals that are produced can then promote breakdown of nearby ozone molecules into more reactive hydroxyl radicals

Either of operations 506a and 506b can be used, alone or in combination, to promote removal of photoresist scum. While either strategy in isolation can be effective in removing photoresist scum, it is believed that these strategies function synergistically to allow for substantial optimization and tuning of photoresist scum removal.

Returning to the embodiment of FIG. 5, the method continues with operation 508, where the substrate is optionally rinsed, for example with water. Rinsing removes the reactive radical and/or ozone chemistry from the substrate, such that the chemistry does not interfere with a subsequent process such as electroplating. At operation 510, the pressure in the process chamber may be raised, for example to atmospheric pressure. In some embodiments, this pressure increase may be omitted, or the pressure may be increased to a level other than atmospheric. For example, where the processing apparatus includes a load lock to transfer the substrate between relevant modules/chambers under controlled conditions (e.g., controlled pressure), such a pressure change may not be needed.

At operation 512, optional post-processing may be performed. Such post-processing can include, e.g., drying the substrate at operation 512a and/or electroplating the substrate at operation 512b. Drying the substrate may be particularly beneficial in cases where the substrate will be stored for some time before further processing. The substrate may be dried in the same or different process chamber in which operations 506 and/or 508 occur. Such drying may be omitted in cases where the substrate is subjected to further processing such as electroplating immediately after any of operations 506, 508, or 510. The substrate may be transferred to an electroplating chamber prior to electroplating in operation 512b. Electroplating processes and apparatus are discussed further below.

One advantage of using aqueous solutions to remove photoresist scum is that liquid-based substrate exposure is easier to control compared to plasma-based substrate exposure. Further, the reactivity of the aqueous solution can be fine-tuned by controlling the concentration of active species in the solution (e.g., the concentration of free radical initiator and/or ozone). Such reactivity tuning is substantially more difficult when plasma is used. The reactivity can be further tuned and localized at the bottom of the feature by using a free radical initiator that produces radicals upon exposure to metal. This localization/preferential increase in reactivity results in improved selectivity and feature shape, for example because less photoresist is undesirably removed from the sidewalls of the feature while removing the photoresist scum from the bottom of the feature.

Another advantage of the disclosed embodiments is that they can be implemented on an electroplating apparatus. Generally, liquid-based processing modules are simpler and easier to incorporate into an electroplating apparatus compared to a module configured to perform plasma processing. For example, certain electroplating apparatus such as the Sabre® 3D tool, available from Lam Research Corporation of Fremont, CA are often equipped with a module referred to as an Advanced Pre-treatment Module (APT), which is configured to perform liquid-based processing. One process such modules are often configured to perform is pre-wetting a substrate surface prior to electroplating, for example to ensure that electrolyte is able to adequately penetrate into the recessed features. The pre-wetting liquid is often delivered through a nozzle that sprays onto the substrate surface. The substrate may rotate to promote uniform liquid delivery. The embodiments herein can be performed in this same type of module. However, care should be taken to ensure that the hardware (e.g., the process chamber and any components therein, as well as the fluid delivery system coupled to the process chamber, or some subset of these components) is capable of withstanding the chemistry that is used. For example, where a free radical initiator solution is used, the hardware should be capable of withstanding exposure to the free radical initiator and any radicals generated therefrom. Similarly, where an ozone solution is used, the hardware should be capable of withstanding exposure to the ozone and any radicals generated therefrom. These chemistries are highly corrosive. Appropriate materials for fabricating the hardware include, but are not limited to, polycarbonate, polyether ether ketone (PEEK), polyurethane, polytetrafluoroethylene (PTFE), glass, titanium, and some grades of stainless steel (e.g. 316).

### Apparatus

The methods herein can be performed on a variety of apparatuses and systems. A suitable apparatus or system includes a process chamber configured for liquid-based processing. In addition, in various embodiments the apparatus or system may also include a process chamber configured for electroplating, which may be separate from but connected with the process chamber configured for liquid-based processing. The apparatus or system may also include a controller configured to cause any one or more of the methods described herein.

FIG. 7 illustrates a process chamber configured for liquid-based processing. This process chamber may be used for any one or more of the operations described in FIG. 5. In this example, the process chamber is configured for spraying or streaming solution onto the substrate. As mentioned above, in other examples immersion may be used instead of spraying or streaming the solution.

In FIG. 7, a substrate 701 is held face-up in the process chamber 703 with substrate holder 702. In some embodiments, the substrate holder is configured to hold the substrate in a substantially horizontal (e.g., “face-up” or “face-down”) orientation during processing. In other embodiments, the substrate holder is configured to hold the substrate in substantially a vertical orientation during processing. The substrate holder may be temperature controlled to allow the substrate to be heated and/or cooled as desired.

In a typical operation, vacuum is first pulled on process chamber 703 though vacuum port 709, which is connected to a vacuum system (not shown). This reduces the pressure in the process chamber 703 to a sub-atmospheric pressure. After much of the gas in the process chamber is removed by the vacuum, solution (e.g., free radical initiator solution, ozone solution, and/or rinse solution) is delivered onto the substrate surface from the nozzle 705 or other mechanism.

The solution is provided to the nozzle 705 through plumbing (not shown). Some or all of the plumbing may be shared among the different solutions. In some cases, separate plumbing may be provided for the different solutions. The plumbing may include one or more mixing vessel for preparing one or more of the solutions. In some cases, a first mixing vessel is provided for preparing an ozone solution, and a second mixing vessel is provided for preparing a free radical initiator solution. The mixing vessels may be fluidically connected to a water source and to one or more reactant source. The reactant source may be gas, liquid, or solid, depending on the chemistry that is used to prepare a particular solution. Various mixing methods may be used. The mixing vessel(s), reactant source, and/or the related plumbing may be temperature controlled. In some embodiments, one or more of these elements may be heated and/or cooled.

In a number of embodiments, it may be beneficial to mix a solution shortly before delivery to the process chamber for processing on a substrate. This may maximize the lifetime over which the chemistry is active in solution. For example, ozone may be incorporated into water to create an ozone solution that is then immediately delivered to the process chamber where a substrate is exposed to the ozone solution. Similar mixing and solution delivery may be used for the free radical initiator solution. In some embodiments, one or more of the solutions is degassed prior to contacting the substrate surface to avoid gas being released as the solution enters the vacuum environment. The degassing may occur before or after the solution is mixed. In some embodiments, degassing may occur before the solution is mixed to ensure that the relevant chemistry is not removed during degassing. The water used for rinsing the substrate may be similarly degassed. As mentioned above, various hardware such as the plumbing, mixing vessel, nozzle 705, and any other components in process chamber 703 are made of a material capable of withstanding the chemistry that is used for descumming.

The substrate may be rotated with motor 707 during processing to ensure complete wetting and exposure of the substrate to the relevant solution. In some embodiments, the solution first contacts the rotating substrate within about 3 cm of the center of the substrate. After wetting the substrate with solution, the substrate may be spun at a low rotation rate with motor 707 to remove entrained solution. In some cases, a thin layer of solution may be left on the substrate surface. Excess solution is drained and exits the vacuum chamber through port 711. The substrate can then be transferred to an electroplating chamber or other process chamber. The process chamber 703 will also typically include a controller 713 comprising program instructions and/or logic for performing various aspects of the methods described herein.

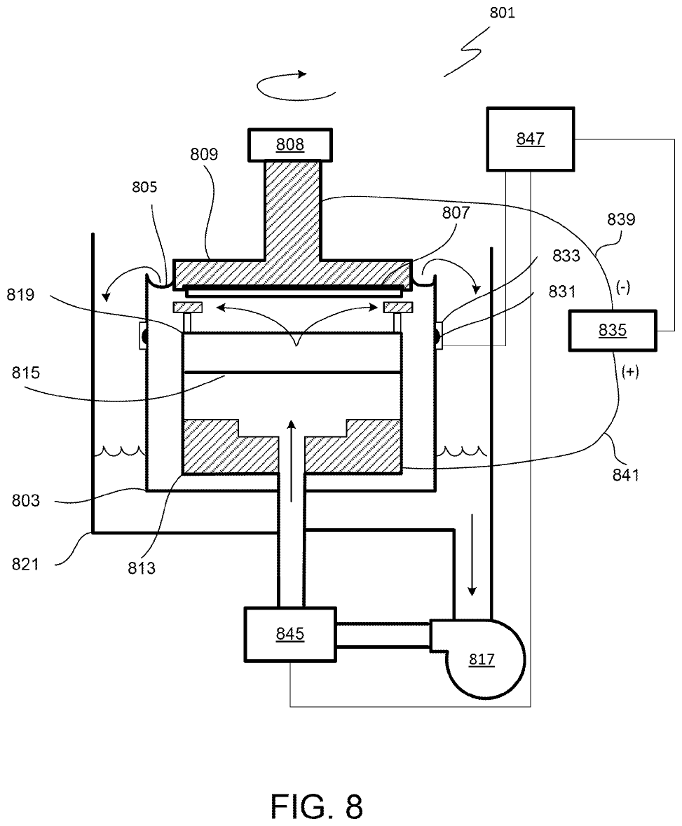

An apparatus in which the electroplating step may be implemented is illustrated in FIG. 8. The apparatus includes one or more electroplating cells in which the substrates (e.g., wafers) are processed. One electroplating cell is shown in FIG. 8 to preserve clarity. To optimize bottom-up electroplating, additives (e.g., accelerators and suppressors) are often added to the electrolyte; however, an electrolyte with additives may react with the anode in undesirable ways. Therefore anodic and cathodic regions of the plating cell are sometimes separated by a membrane so that plating solutions of different composition may be used in each region. Plating solution in the cathodic region is called catholyte; and in the anodic region, anolyte. A number of engineering designs can be used in order to introduce anolyte and catholyte into the plating apparatus.

Referring to FIG. 8, a diagrammatical cross-sectional view of an electroplating apparatus 801 in accordance with one embodiment is shown. The plating bath 803 contains the plating solution, which is shown at a level 805. The catholyte portion of this vessel is adapted for receiving substrates in a catholyte. A wafer 807 is immersed into the plating solution and is held by, e.g., a substrate holder 809 (e.g., a “clamshell” substrate holder), mounted on a rotatable spindle 811, which allows rotation of substrate holder 809 together with the wafer 807. A general description of a clamshell-type plating apparatus having aspects suitable for use with this invention is described in detail in U.S. Pat. No. 6,156,167 issued to Patton et al., and U.S. Pat. No. 6,800,187 issued to Reid et al, which are incorporated herein by reference for all purposes.

An anode 813 is disposed below the wafer within the plating bath 803 and is separated from the wafer region by a membrane 815, preferably an ion selective membrane. For example, Nafion™ cationic exchange membrane (CEM) may be used. The region below the anodic membrane is often referred to as an “anode chamber.” The membrane 815 allows ionic communication between the anodic and cathodic regions of the plating cell, while preventing the particles generated at the anode from entering the proximity of the wafer and contaminating it. The anode membrane is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated herein by reference for all purposes. Ion exchange membranes, such as cationic exchange membranes are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating the ions from the plating solution are deposited on the substrate. The metal ions must diffuse through the diffusion boundary layer and into the TSV hole. A typical way to assist the diffusion is through convection flow of the electroplating solution provided by the pump 817. Additionally, a vibration agitation or sonic agitation member may be used as well as wafer rotation. For example, a vibration transducer 808 may be attached to the substrate holder 809.

The plating solution is continuously provided to plating bath 803 by the pump 817. Generally, the plating solution flows upwards through the membrane 815 and a diffuser plate 819 to the center of wafer 807 and then radially outward and across wafer 807. The plating solution also may be provided into anodic region of the bath from the side of the plating bath 803. The plating solution then overflows plating bath 803 to an overflow reservoir 821. The plating solution is then filtered (not shown) and returned to pump 817 completing the recirculation of the plating solution. In certain configurations of the plating cell, a distinct electrolyte is circulated through the portion of the plating cell in which the anode is contained while mixing with the main plating solution is prevented using sparingly permeable membranes or ion selective membranes.

A reference electrode 831 is located on the outside of the plating bath 803 in a separate chamber 833, which chamber is replenished by overflow from the plating bath 803. Alternatively, in some embodiments the reference electrode is positioned as close to the substrate surface as possible, and the reference electrode chamber is connected via a capillary tube or by another method, to the side of the wafer substrate or directly under the wafer substrate. In some of the preferred embodiments, the apparatus further includes contact sense leads that connect to the wafer periphery and which are configured to sense the potential of the metal seed layer at the periphery of the wafer but do not carry any current to the wafer.

A reference electrode 831 is typically employed when electroplating at a controlled potential is desired. The reference electrode 831 may be one of a variety of commonly used types such as mercury/mercury sulfate, silver chloride, saturated calomel, or copper metal. A contact sense lead in direct contact with the wafer 807 may be used in some embodiments, in addition to the reference electrode, for more accurate potential measurement (not shown).

A power supply 835 (e.g., a DC power supply) can be used to control current flow to the wafer 807. A power supply capable of supplying pulse current or applying a pulsed voltage may also be suitable, and the pulses may be various combination of forward (plating), off (no plating) and reverse (de plating) segments of various durations, repeated and/or modulated over the process. The power supply 835 has a negative output lead 839 electrically connected to wafer 807 through one or more slip rings, brushes and contacts (not shown). The positive output lead 841 of power supply 835 is electrically connected to an anode 813 located in plating bath 803. The power supply 835, a reference electrode 831, and a contact sense lead (not shown) can be connected to a system controller 847, which allows, among other functions, modulation of current and potential provided to the elements of electroplating cell. For example, the controller may allow electroplating in potential-controlled and current-controlled regimes. The controller may include program instructions specifying current and voltage levels that need to be applied to various elements of the plating cell, as well as times at which these levels need to be changed. When forward current is applied, the power supply 835 biases the wafer 807 to have a negative potential relative to anode 813. This causes an electrical current to flow from anode 813 to the wafer 807, and an electrochemical reduction (e.g. Cu²⁺2 e⁻=Cu⁰) occurs on the wafer surface (the cathode), which results in the deposition of the electrically conductive layer (e.g. copper) on the surfaces of the wafer.

The apparatus may also include a heater 845 for maintaining the temperature of the plating solution at a specific level. The plating solution may be used to transfer the heat to the other elements of the plating bath. For example, when a wafer 807 is loaded into the plating bath the heater 845 and the pump 817 may be turned on to circulate the plating solution through the electroplating apparatus 801, until the temperature throughout the apparatus becomes substantially uniform. In one embodiment the heater is connected to the system controller 847. The system controller 847 may be connected to a thermocouple to receive feedback of the plating solution temperature within the electroplating apparatus and determine the need for additional heating.

As mentioned above, an electroplating cell such as the one shown in FIG. 8 can be incorporated into a larger substrate processing apparatus. The apparatus may be configured to perform various process operations in addition to electroplating. For instance, the apparatus may include one or more process chamber configured for water-based processing (e.g., as described in FIG. 7) to expose a substrate to an ozone solution and/or to a free radical initiator solution, as described herein. Including these different types of process chambers in a single apparatus provides various benefits including, but not limited to, providing a controllable atmosphere in which to transfer the substrate between relevant operations. In addition, such an apparatus eliminates the need for a separate plasma-based photoresist scum removal tool, thereby minimizing capital costs.

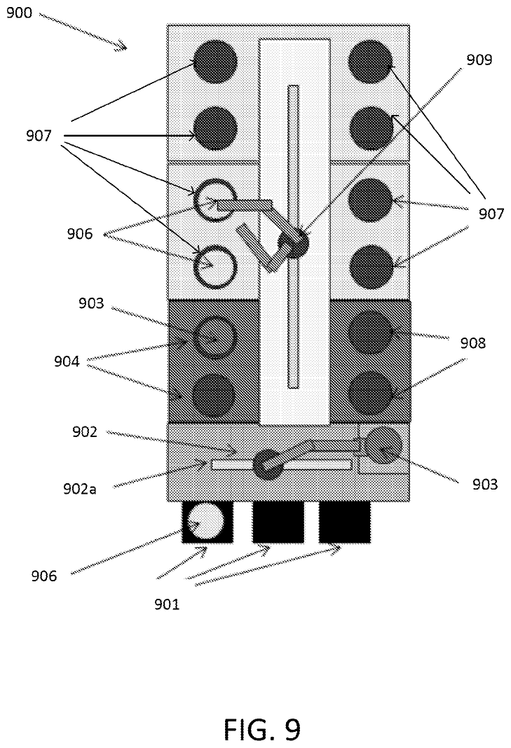

One embodiment of an electrodeposition apparatus 900 is schematically illustrated in FIG. 9. In this embodiment, the electrodeposition apparatus 900 has a set of electroplating cells 907, each can contain an electroplating bath, in a paired or multiple “duet” configuration. In addition to electroplating per se, the electrodeposition apparatus 900 may perform a variety of other electroplating related processes and sub-steps, such as spin-rinsing, spin-drying, metal and silicon wet etching, electroless deposition, pre-wetting and pre-chemical treating (e.g., using the solutions described herein), reducing, annealing, electro-etching and/or electropolishing, photoresist stripping, and surface pre-activation, for example. The electrodeposition apparatus 900 is shown schematically looking top down in FIG. 9, and only a single level or “floor” is revealed in the figure, but it is to be readily understood by one having ordinary skill in the art that such an apparatus, e.g., the Lam Sabre™ 3D tool, can have two or more levels “stacked” on top of each other, each potentially having identical or different types of processing stations.

Referring once again to FIG. 9, the substrates 906 that are to be electroplated are generally fed to the electrodeposition apparatus 900 through a front end loading FOUP 901 and, in this example, are brought from the FOUP to the main substrate processing area of the electrodeposition apparatus 900 via a front-end robot 902 that can retract and move a substrate 906 driven by a spindle 903 in multiple dimensions from one station to another of the accessible stations—two front-end accessible stations 904 and also two front-end accessible stations 908 are shown in this example. The front-end accessible stations 904 and 908 may include, for example, pre-treatment stations (e.g., using the solutions described herein), and spin rinse drying (SRD) stations. Lateral movement from side-to-side of the front-end robot 902 is accomplished utilizing robot track 902a. Each of the substrates 906 may be held by a cup/cone assembly (not shown) driven by a spindle 903 connected to a motor (not shown), and the motor may be attached to a mounting bracket 909. Also shown in this example are the four “duets” of electroplating cells 907, for a total of eight electroplating cells 907. A system controller (not shown) may be coupled to the electrodeposition apparatus 900 to control some or all of the properties of the electrodeposition apparatus 900. The system controller may be programmed or otherwise configured to execute instructions according to processes described herein.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer.

In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### EXAMPLES

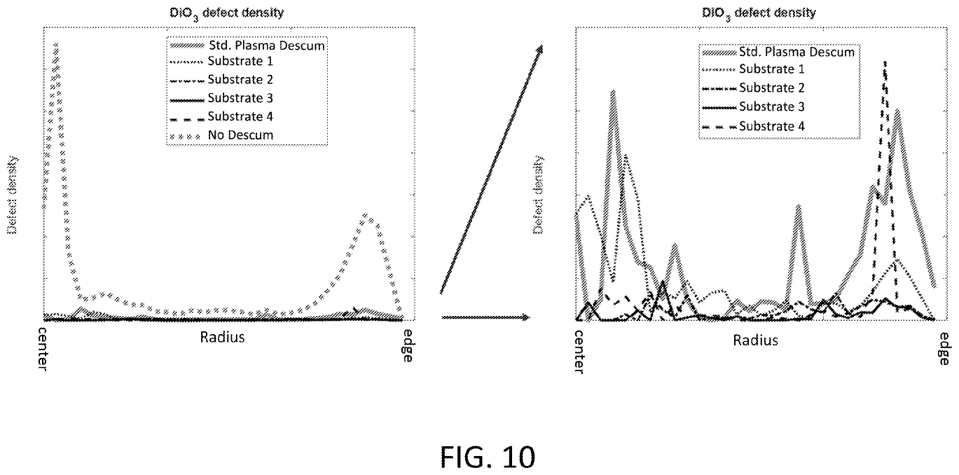

Various working examples have shown that the methods described herein can be used to remove photoresist scum from a substrate with high quality results, including for both positive tone and negative tone photoresist. One such example is described with reference to FIG. 10. FIG. 10 shows defect densities for substrates patterned with positive tone photoresist exposed to either a standard oxygen plasma photoresist scum removal process or to a liquid water-based photoresist scum removal process. The liquid water-based processes involved exposing the substrates to ozone solutions. The curves in FIG. 10 reflect different ozone concentrations and exposure times. The ozone concentrations ranged between a few ppm and about 50 ppm, and the durations ranged between about 1 minute and a few minutes. After descumming, the substrates were electroplated and then analyzed for defects. FIG. 10 also shows results for a substrate that was electroplated without any prior descumming process and demonstrates the effectiveness of the descumming process. In each graph of FIG. 10, the x-axis corresponds to the distance from the center of the substrate (radius, r), and the y-axis corresponds to the defect density measured at that radius. A low defect density indicates that the photoresist scum removal process was relatively successful, while a high defect density indicates that a substantial amount of photoresist scum remained on the substrate surface, where it interfered with later electroplating to cause formation of defects.

The graph on the left-hand portion of FIG. 10 shows results from both (i) a substrate which did not undergo any descumming process, and (ii) the substrates which underwent descumming. The substrate that was not subjected to descumming showed extremely high defect density.

The graph on the right-hand portion of FIG. 10 shows an expanded region of the graph on the left-hand portion of FIG. 10, for clarity. Only the results from substrates that were subjected to descumming fit within this scale. Even short exposures to an ozone solution resulted in substantial removal of photoresist scum and a related minimization of defects after electroplating.

Table 1, below, shows average increase in feature CD for substrates having a variety of different standardized features thereon after either a liquid water-based photoresist scum removal process involving exposure of the substrate to an ozone solution or to an oxygen plasma-based photoresist scum removal process involving exposure of the substrate to an oxygen plasma. In this example, the photoresist was a positive tone photoresist. Each substrate included a variety of features having different geometries (e.g., a circular pad, a square pad, and lines, with critical dimensions ranging between about 5 μm and about 100 μm). Each substrate had the same layout of features compared to other substrates.

Substrates that had not been subjected to any photoresist scum removal process were served as a baseline to demonstrate the degree to which the critical dimension of the various features changed during the photoresist scum removal processes.

TABLE 1

| | Increase in Feature CD: | Increase in Feature CD: |
|---|---|---|
| | Ozone solution-based | Oxygen plasma-based |
| | photoresist removal process | photoresist removal process |
| | (μm) | (μm) |
| Average | 0.24 | 0.23 |

There was a small but detectable increase in critical dimension for all substrates subjected to a photoresist scum removal process. Because both the liquid water-based process and the plasma-based process are selected to fully remove the photoresist scum with the least amount of processing, this increase in critical dimension is expected. Notably, the liquid water-based process and the oxygen plasma-based process resulted in very similar increases in critical dimension.

A subset of this example is shown in FIG. 11. Specifically, FIG. 11 shows the line widths for the 10 μm line feature type. The results in FIG. 11 show that exposure of the substrate to either a liquid water-based photoresist scum removal process or to an oxygen plasma-based photoresist scum removal process results in a slight but measurable increase in the critical dimension of the features thereon. The increase in critical dimension was comparable between both types of photoresist scum removal processes.

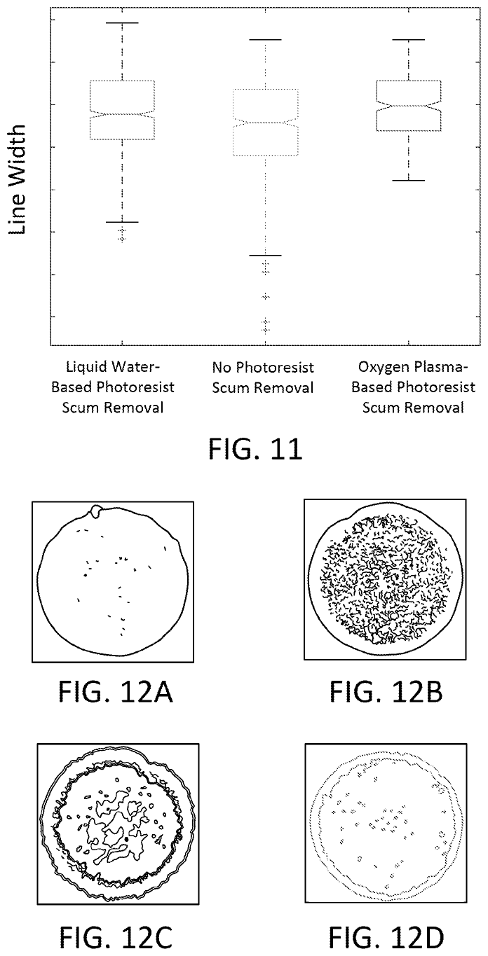

In another example, a collection of substrates having features patterned into negative tone photoresist and having a substantial amount of photoresist scum remaining in the features was analyzed to demonstrate the effectiveness of the liquid water-based photoresist scum removal processes described herein. The photoresist was relatively thick. Half of the substrates (e.g., wafers 1, 4, 5, and 7) were not subjected to any photoresist scum removal process. The remaining half of the substrates (e.g., wafers 2, 3, 6, and 8) were subjected to a liquid water-based photoresist scum removal process that involved exposing the substrate to an ozone solution. All of the substrates were electroplated before analysis. Many features on each substrate were examined. The features were examined to determine whether the electroplating process was successful. Each feature was categorized as either good, bad, defective, or missing. A good fill shows no visible defects with clean feature edges. Photoresist remnants may be present but are not considered defects in this analysis. An example of a good fill is shown in FIG. 12A, shown from the top down. A bad fill shows small defects over the surface of the feature. These defects can increase resistance during electroplating, leading to non-uniform or otherwise low quality electroplating results. An example of a bad fill is shown in FIG. 12B, shown from the top down. A defective fill includes large defects that leave most of the feature surface unpalatable. Such features often do not plate completely and/or undesirably fall off the substrate during a subsequent photoresist stripping step. An example of a defective fill is shown in FIG. 12C, shown from the top down. A missing fill corresponds to a feature that is entirely or almost entirely unplated. An example of a missing fill is shown in FIG. 12D, shown from the top down.

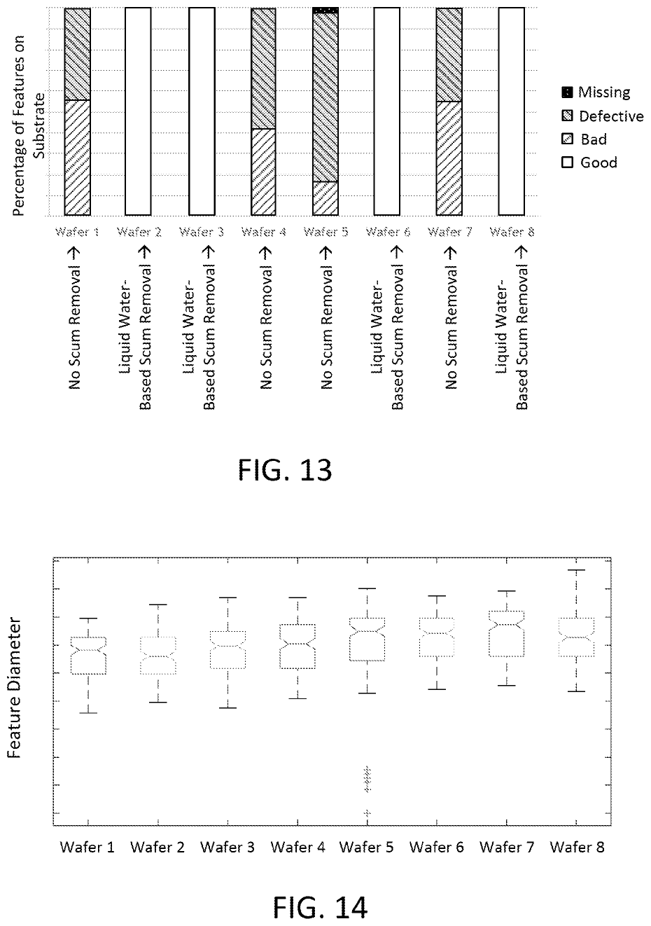

FIG. 13 shows that all of the examined features on the substrates that were not subjected to any photoresist scum removal process showed bad, defective, or missing fill results. By contrast, FIG. 13 shows that all of the examined features on the substrates that were subjected to the liquid water-based photoresist removal process (e.g., involving exposure to the ozone solution) showed good fill results, with no visible defects attributable to the photoresist scum.

In a related example, a collection of substrates having features patterned into negative tone photoresist and having a substantial amount of photoresist scum in the features was analyzed to demonstrate the effectiveness of the liquid water-based photoresist scum removal processes described herein. Half of the substrates (e.g., wafers 1, 4, 5, and 7) were not subjected to any photoresist scum removal processes. The remaining half of the substrates (e.g., wafers 2, 3, 6, and 8) were subjected to a liquid water-based photoresist scum removal process that involved exposing the substrates to an ozone solution. The substrates were analyzed to determine the diameter of the features. The feature diameters related to this example are shown in in FIG. 14. Notably, there was no detectable difference between feature diameters for any of the substrates. In other words, exposing the substrate to the ozone solution did not result in widening the feature diameters. By contrast, conventional processes that are effective in removing photoresist scum typically also remove some amount of photoresist, resulting in wider features. As such, the disclosed methods are believed to be especially beneficial when used in combination with negative tone photoresist (although positive tone photoresist can also be used).

The examples described herein show that the disclosed methods can be effectively used to remove scum on both negative tone and positive tone photoresist. Further, the examples show that the disclosed methods can be used even on relatively thick photoresist. Where similar liquid-based photoresist removal processes have been used in the past, they have usually been limited to cases where the photoresist is a relatively thin (e.g., <1 μm) positive tone photoresist.

These promising examples provided unexpected results. Previous liquid-based ozonated water treatments have been used in the context of either (1) completely removing a layer of photoresist, or (2) completely removing photoresist remnants after another process has removed the bulk of the photoresist. Such treatments have not been used previously to remove photoresist scum while maintaining the bulk of the photoresist (e.g., while maintaining the features formed in the photoresist). As such, it was surprising that the disclosed treatments could be used to remove photoresist scum while maintaining the features formed in the bulk of the photoresist. Further, previous attempts at using ozone solutions to remove bulk negative tone photoresist have not been successful. Therefore, it was surprising that such treatments could be successful in removing photoresist scum arising from such negative tone photoresist. While ozone has been used to remove photoresist scum in very limited circumstances, these methods have only been practiced or considered in the context of gas-based processing, where the ozone is provided to the substrate in gaseous form. At least in part because the previous attempts to remove bulk negative tone photoresist using ozone solutions were unsuccessful, as mentioned above, it was believed that liquid-based ozone solution treatments would be less likely to succeed compared to gas-based methods.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of processing a substrate, the method comprising:
receiving the substrate in a process chamber, the substrate comprising a layer of photoresist with features patterned therein, wherein photoresist scum is present in the features; and
exposing the substrate to a solution comprising water and one or more chemistries, the solution capable of removing at least a portion of the photoresist scum from the features.

2. The method of claim 1, wherein the solution is an ozone solution comprising water and ozone.

3. The method of claim 2, wherein the ozone solution has an ozone concentration between about 5 ppm and about 500 ppm.

4. The method of claim 1, wherein the solution is a free radical initiator solution comprising water and a free radical initiator.

5. The method of claim 4, wherein the free radical initiator comprises one or more chemistry selected from the group consisting of a peroxide, an azo compound, an alkyl halide compound, and combinations thereof.

6. The method of claim 5, wherein the free radical initiator comprises one or more chemistry selected from the group consisting of hydrogen peroxide, benzoyl peroxide, 2,2′-Azobis(2-methylpropionamidine) dihydrochloride, and combinations thereof.

7. The method of claim 4, wherein the free radical initiator solution has a free radical initiator concentration between about 5 ppm and about 1000 ppm.

8. The method of claim 4, wherein the free radical initiator decomposes to form radicals that remove at least a portion of the photoresist scum from the features, and wherein the free radical initiator preferentially decomposes near a bottom of the features compared to a top of the features.

9. The method of claim 1, wherein exposing the substrate to the solution comprises exposing the substrate to a first solution followed by exposing the substrate to a second solution, wherein the first solution is a free radical initiator solution comprising water and a free radical initiator, and the second solution is an ozone solution comprising water and ozone.

10. The method of claim 9, wherein the free radical initiator decomposes to form radicals, and wherein the radicals formed from the free radical initiator interact with the ozone to form hydroxyl radicals.

11. The method of claim 1, wherein the solution comprises both a free radical initiator and ozone such that the substrate is simultaneously exposed to both the free radical initiator and to ozone.

12. The method of claim 1, wherein exposing the substrate to the solution comprises spraying or streaming the solution onto the substrate, or immersing the substrate in the solution.

13. The method of claim 1, wherein the photoresist is a negative tone photoresist or a positive tone photoresist.

14. The method of claim 1, further comprising electroplating metal into the features after exposing the substrate to the solution.

15. An apparatus for processing a substrate, the apparatus comprising:
a process chamber;
an inlet to the process chamber configured to provide a solution to the process chamber;
and
a controller configured to cause:
receiving the substrate in the process chamber, the substrate comprising a layer of photoresist with features patterned therein, wherein photoresist scum is present in the features, and
providing the solution to the process chamber via the inlet and exposing the substrate to the solution, the solution comprising water and one or more chemistries capable of removing at least a portion of the photoresist scum from the features.

16. The apparatus of claim 15, further comprising a nozzle fluidically connected to the inlet, wherein the nozzle sprays or streams the solution onto the substrate.

17. The apparatus of claim 15, further comprising a substrate support configured to immerse the substrate in the solution.

18. The apparatus of claim 15, wherein the inlet comprises one or more material selected from the group consisting of polycarbonate, polyether ether ketone (PEEK), polyurethane, polytetrafluoroethylene (PTFE), glass, titanium, stainless steel, and combinations thereof.

19. The apparatus of claim 15, further comprising a mixing vessel and/or plumbing to prepare the solution by combining (i) the water and (ii) the one or more chemistries capable of removing at least a portion of the photoresist scum.

20. The apparatus of claim 15, wherein the controller is further configured to cause preparing the solution by combining (i) the water, and (ii) the one or more chemistries capable of removing at least a portion of the photoresist scum, no more than about 10 minutes before the substrate is exposed to the solution.

21. The apparatus of claim 15, further comprising a second process chamber configured for electroplating, wherein the process chamber and the second process chamber are provided together such that the substrate can be transferred from the process chamber to the second process chamber under a controlled atmosphere, without removing the substrate from the apparatus.
